(19) United States
(12) Patent Application Publication
(10) Pub. No.: US 2014/0076828 A1
(43) Pub. Date: Mar. 20, 2014

(54) MOUNTING DEVICE FOR FAN

(71) Applicants: MING-YU LIU, Shenzhen City, Guangdong Province (CN); PING-CHUAN DENG, Shenzhen City, Guangdong Province (CN); AN-GANG LIANG, Shenzhen City, Guangdong Province (CN)

(72) Inventors: MING-YU LIU, Shenzhen City, Guangdong Province (CN); PING-CHUAN DENG, Shenzhen City, Guangdong Province (CN); AN-GANG LIANG, Shenzhen City, Guangdong Province (CN)

(21) Appl. No.: 13/629,499

(22) Filed: Sep. 27, 2012

(30) Foreign Application Priority Data
Sep. 14, 2012 (CN) 2012103398223

(51) Int. Cl. H05K 7/20; H05K 7/14

(52) U.S. Cl. 211/26

(57) ABSTRACT

A mounting device for mounting a fan includes a board, a receiving frame for receiving the fan, and a locking member. The board defines a vent and a positioning hole adjacent to the vent. The receiving frame includes two opposite sidewalls. A fixing leg extends down from a bottom of the receiving frame to be extended through the positioning hole and blocked by a bottom of the board. A tab extends out from the receiving frame. A fastener extends through the tab and is engaged in the board. The locking member includes a bar to block the fan and two fixing arms connected to opposite ends of the bar and being fixed to the sidewalls, respectively.

### BACKGROUND

1. Technical Field

The present disclosure relates to a device for mounting a fan.

2. Description of Related Art

Many electronic devices use fans to cool electronic components. A fan is ordinarily mounted in the electronic device by a plurality of screws, which makes it difficult and time-consuming to replace or remove the fan for repair.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device including a receiving frame, together with a plurality of fans.

FIG. 2 is an enlarged, inverted view of the receiving frame of FIG. 1.

FIG. 3 is a partly assembled, isometric view of FIG. 1.

FIG. 4 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

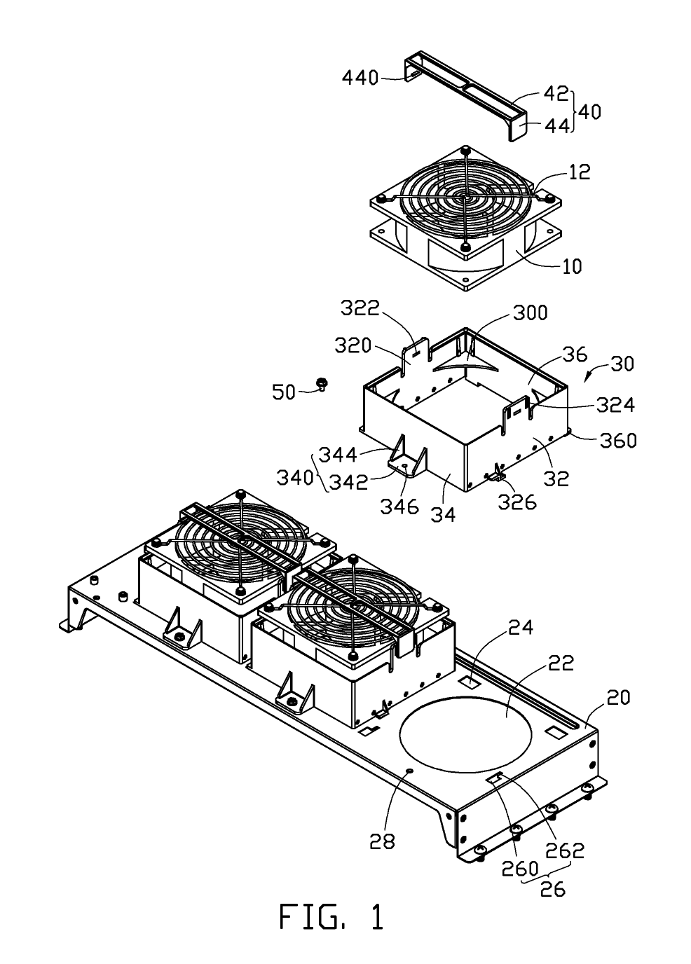

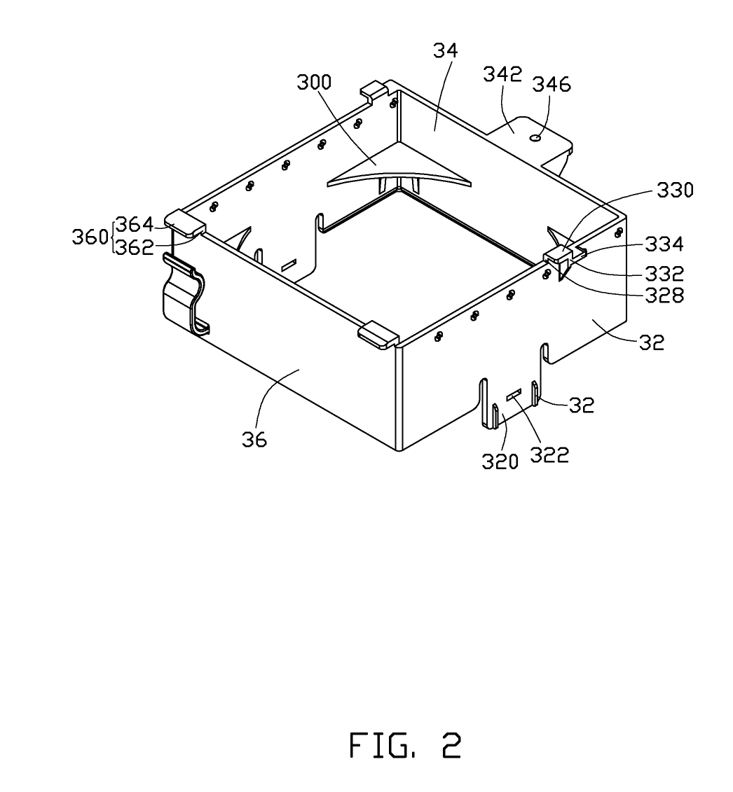

FIGS. 1 and 2 show an exemplary embodiment of a mounting device for mounting a plurality of fans 10. Each fan 10 includes a protecting portion 12 attached to an inlet of the fan 10. The mounting device includes a board 20, a plurality of receiving frames 30, and a plurality of locking members 40.

The board 20 is mounted in a chassis (not shown). The board 20 longitudinally defines a plurality of vents 22, two rectangular positioning holes 24 in a first side of the board 20 and at opposite sides of each vent 22, and two limiting holes 26 in a second side of the board 20 opposite to the first side and at opposite sides of each vent 22. A threaded hole 28 is defined in the second side of the board 20, between the limiting holes 26. Each limiting hole 26 includes a rectangular access 260, and a fixing hole 262 communicating with an end of a side of the access 260 adjacent to the corresponding vent 22.

Each receiving frame 30 is rectangular, and includes two opposite sidewalls 32, a front wall 34 connected between front ends of the sidewalls 32, and a rear wall 36 connected between rear ends of the sidewalls 32.

Four supporting portions 300 perpendicularly extend inward from opposite ends of an inner surface of the front and rear walls 32 and 34. Each supporting portion 300 is connected to the adjacent sidewall 32. A fixing portion 340 protrudes out from a bottom side of an outer surface of the front wall 34 opposite to the supporting portions 300. The fixing portion 340 includes a tab 342 perpendicularly extending out from the front wall 34 and two triangular connection pieces 344 perpendicularly connected between opposite ends of the tab 342 and the front wall 34. The tab 342 defines a through hole 346. Two fixing legs 360 extend down from a bottom side of the rear wall 36. Each fixing leg 360 includes an extension piece 362 extending down from the bottom of the rear wall 36 and a blocking piece 364 perpendicularly extending out from a bottom side of the extension piece 360 opposite to the rear wall 36.

A plate 320 extends up from a center of a top side of each sidewall 32. Each plate 320 defines an engaging hole 322. Two blocks 324 protrudes out from an outer surface of each plate 320, at opposite sides of the corresponding engaging hole 322. A latch 326 is formed at a bottom side of each sidewall 32. Each latch 326 includes an extension piece 328 extending down from the bottom of the corresponding sidewall 32, a blocking piece 330 perpendicularly extending out from a bottom side of the extension piece 328 opposite to the sidewall 32, a rib 332 perpendicularly connected to front sides of the extension piece 328 and the blocking piece 330, and a dust-proof piece 334 perpendicularly extending forward from a front side of the rib 332 and connected to the corresponding sidewall 32. The ribs 332 can pin up the extension piece 328 and the blocking piece 330, to prevent the extension piece 328 and the blocking piece 330 from breaking off.

The locking member 40 includes a substantially H-shaped bar 42 and two fixing arms 44 extending down from opposite ends of the bar 42. A projection 440 protrudes from an inner surface of each fixing arm 44.

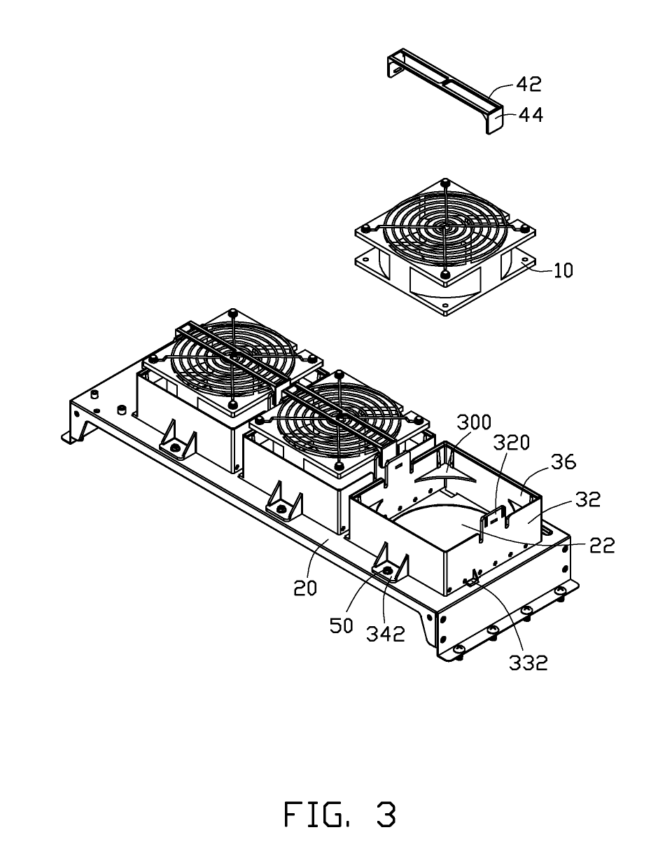

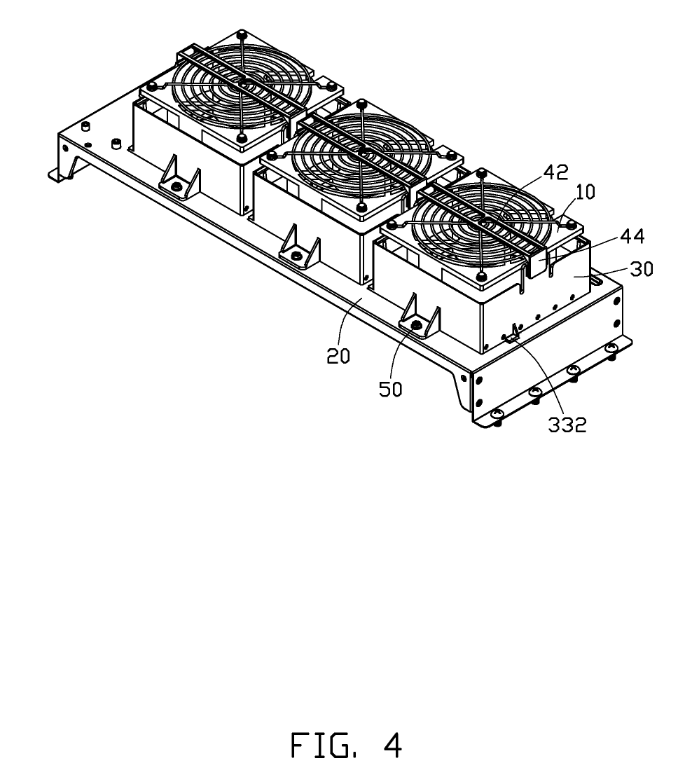

Referring to FIGS. 3 and 4, in fixing each receiving frame 30 to the board 20, the receiving frame 30 is supported on the board 20 and is aligned with one of the vents 22. The fixing legs 360 are received in the corresponding positioning holes 24, and the latches 326 are received in the corresponding accesses 260. The receiving frame 30 is then slid toward the first side of the board 20. The blocking pieces 364 and 330 are blocked by a bottom surface of the board 20. The extension pieces 328 are engaged in the corresponding fixing holes 262. A fastener 50 extends through the through hole 346 and then is engaged in the threaded hole 28 of the board 20, to fix the receiving frame 30 to the board 20. The dust-proof pieces 334 cover the corresponding accesses 260, to prevent dust from extending through the accesses 260.

In installing each fan 10, the fan 10 is received in one of the receiving frame 30. The fan 10 is supported on the supporting portions 300. A locking member 40 is then attached to a top of the receiving frame 30. The projections 440 are engaged in the corresponding engaging hole 322. Each fixing arm 44 is sandwiched between the corresponding blocks 324. The bar 42 blocks the fan 10, to fix the fan 10 in the receiving frame 30.

In uninstalling one of the fans 10 from a corresponding one of the receiving frame 30, the corresponding fixing arms 44 are deformed away from each other to disengage the projections 440 from the corresponding engaging holes 322. Therefore, the fan 10 is readily taken out of the receiving frame 30.

In the embodiment, a distance from one of the limiting holes 26 adjacent to each vent 22 to the second side of the board 20 is different from a distance from the other one of the limiting holes 26 to the second side of the board 20. Therefore, two adjacent limiting holes 26 between two adjacent vents 22 are staggered from each other and can be close to each other in the longitudinal direction of the board 20, thereby saving space of the board 20.

In another embodiment, the two limiting holes 26 adjacent to each vent 22 can be in alignment with each other.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for mounting a fan, comprising:
a board defining a vent and a positioning hole adjacent to the vent;
a receiving frame for receiving the fan, the receiving frame comprising two opposite sidewalls, a fixing leg extending down from the receiving frame to be extended through the positioning hole and blocked by a bottom of the board, a tab extending out from the receiving frame;
a fastener extending through the tab and engaging in the board; and
a locking member comprising two fixing arms to be fixed to the sidewalls and a bar connected between the fixing arms for blocking the fan in the receiving frame.

2. The mounting device of claim 1, wherein each sidewall defines an engaging hole, a projection protrudes from an inner surface of each fixing arm to be engaged in one of the engaging holes.

3. The mounting device of claim 2, wherein two blocks protrude from each sidewall at opposite sides of the corresponding engaging hole, to sandwich a corresponding one of the fixing arms.

4. The mounting device of claim 2, wherein a plate extends up from each sidewall, each engaging hole is defined in a corresponding one of the plates.

5. The mounting device of claim 1, wherein the fixing leg comprises a first extension piece extending down from the receiving frame and a first blocking piece perpendicularly extending out from the first extension piece to be blocked by the bottom of the board.

6. The mounting device of claim 5, wherein the receiving frame further comprises a front wall connected between front ends of the sidewalls, and a rear wall connected between rear ends of the sidewalls, the tab extends out from the front wall, the fixing leg extends down from the rear wall, and the positioning hole is defined behind the vent.

7. The mounting device of claim 6, wherein two limiting holes are defined in the board at opposite ends of a front side of the vent opposite to the positioning hole, two latches extend down from the receiving frame to be extended through the corresponding limiting holes and blocked by the bottom of the board.

8. The mounting device of claim 7, wherein each limiting hole comprises an access and a fixing hole communicating with an end of the access, each latch comprises a second extension piece extending down from the receiving frame and engaged in a corresponding one of the fixing holes, and a second blocking piece perpendicularly extending out from the second extension piece to be blocked by the bottom of the board.

9. The mounting device of claim 8, wherein each latch further comprises a rib perpendicularly connected to front sides of the second extension piece and the second blocking piece, and a dust-proof piece perpendicularly extending forward from a front side of the rib.

10. The mounting device of claim 7, wherein one of the limiting holes is positioned in front of and at a side of the other one of the limiting holes.

11. The mounting device of claim 1, wherein the receiving frame comprises a front wall and a rear wall connected between the sidewalls, a supporting portion extends from an inner surface of each of the front and rear walls to support the fan.

12. A mounting device for mounting a fan, comprising:
a board defining a vent and a positioning hole adjacent to the vent;
a receiving frame fixed on the board, and comprising two opposite sidewalls cooperatively enclosing the vent, a supporting portion extending from each of the sidewalls for supporting the fan; and
a locking member comprising a bar abutting a top of the fan, and two fixing arms extending from opposite ends of the bar and detachably fixed to the sidewalls.

13. The mounting device of claim 12, wherein each sidewall defines an engaging hole, a projection protrudes from an inner surface of each fixing arm to be engaged in one of the engaging holes.

14. The mounting device of claim 12, wherein two blocks protrude out from each sidewall at opposite sides of the corresponding engaging hole, to sandwich a corresponding one of the fixing arms.

15. The mounting device of claim 12, wherein the board defining a positioning hole at a rear side of the vent, and a threaded hole at a front side of the vent, the receiving frame further comprises a front wall connected between front ends of the sidewalls, and a rear wall connected between rear ends of the sidewalls, a tab extends out from the front wall, a fixing leg extends down from the rear wall to engage in the positioning hole, a fastener extends through the tab to engage in the threaded hole.

16. The mounting device of claim 15, wherein the fixing leg comprises an extension piece extending down from the receiving frame and a blocking piece perpendicularly extending out from the extension piece to be blocked by the bottom of the board.

17. The mounting device of claim 12, wherein two limiting holes are defined in the board at opposite ends of a front side of the vent, two latches respectively extend down from the sidewalls to be extended through the corresponding limiting holes and blocked by the bottom of the board.

18. The mounting device of claim 17, wherein each limiting hole comprises an access, and a fixing hole communicating with an end of the access, each latch enters the limiting hole through the access and engages in the fixing hole.
